(19) United States
(12) Patent Application Publication
(10) Pub. No.: US 2015/0179881 A1
(43) Pub. Date: Jun. 25, 2015

(54) NITRIDE LED STRUCTURE WITH DOUBLE GRADED ELECTRON BLOCKING LAYER

(71) Applicant: SHARP KABUSHIKI KAISHA, Osaka (JP)

(72) Inventors: Mathieu Sénès, Harwell (GB); Tadashi Takeoka, Hiroshima (JP)

(73) Assignee: SHARP KABUSHIKI KAISHA, Osaka (JP)

(21) Appl. No.: 14/139,915

(22) Filed: Dec. 24, 2013

(51) Int. Cl. H01L 33/14; H01L 33/00

(52) U.S. Cl. CPC H01L 33/145; H01L 33/0025

(57) ABSTRACT

A group III nitride-based light emitting device includes an n-type semiconductor layer; a first p-type semiconductor layer; an active region; and an electron blocking region comprising AlGaInN located between the active region and the first p-type semiconductor layer, and including at least an upgraded layer and a downgraded layer. An aluminium composition of the upgraded layer of the electron blocking region increases from an active region side to a first p-type semiconductor layer side of the electron blocking region, and an aluminium composition of the downgraded layer of the electron blocking region decreases from the active region side to the first p-type semiconductor layer side of the electron blocking region. The nitride-based light emitting device may be a light emitting diode or a laser diode.

### TECHNICAL FIELD

The present invention relates to the field of light emitting devices, and more particularly to the improvement of the light output efficiency of a light emitting device.

### BACKGROUND OF THE INVENTION

Light emitting diodes (LEDs) are key components to a wide range of applications that include backlighting units for liquid crystal displays, headlamps for automobiles, or general lighting. For example, III-nitride semiconductor based blue and green emitting LEDs are widely used in these applications. However, such LEDs still suffer from degraded performance at high current injection caused by a phenomenon commonly referred to in the art as “efficiency droop”.

A standard LED structure includes an electron supply layer (e.g. generally n-type semiconductor), a hole supply layer (e.g. p-type semiconductor) and an active region (e.g. light emitting area which can include single or multiple quantum wells). A multiple quantum well structure includes quantum wells and quantum barriers. It has been reported in the literature that one possible cause of the efficiency droop may be due to the injected electrons leaking out of the active region. To limit this phenomenon, an electron blocking layer (EBL) made of Aluminium Gallium Nitride (AlGaN) is generally placed between the active region and the hole supply layer. An EBL with a large energy bandgap is then preferred to limit as much as possible the electrons leaking out of the active region. However, making an EBL with large energy band gap, i.e. with high aluminium composition, is difficult to grow with high quality material because of the lattice mismatch between GaN and AlGaN. Moreover, an EBL with high aluminium composition leads to severe band bending due to the internal polarisation fields at the c-plane nitride hetero-junction, especially at the interfaces between the last quantum barrier of the active region and the EBL, and also at the interface between EBL and hole supply layer (as shown in FIG. 1). Then the valence band at these interfaces exhibits a spike, which prevents the holes to be injected efficiently in the active region.

Therefore, it is desirable to reduce the effect of the internal polarisation fields on the hole injection and improve the material quality while having a high aluminium composition in the EBL, so the light output power of III-nitride LEDs is improved.

A known approach for reducing the effect of the internal polarisation field at the interface between the active region and the EBL is to grade the composition of the EBL to reduce the spike in the valence band. This approach is described in JP patent 5083817 (issued on Nov. 28, 2012). It teaches that a continuous or discrete grading of the aluminium composition from the active region side of the EBL leads to a reduction of the spike in the valence band, thus improving the hole injection. However, in this patent, the EBL is directly grown on top of the last quantum well of the active region. In that particular case, even if a spike in the valence band exists at the interface between the last quantum well and the EBL, this spike would be in the quantum well, so the holes would accumulate in this quantum well.

The effect of such valence band spike on the efficiency of the carrier recombination is then limited. Moreover, it is difficult to grow an EBL directly on top of the last quantum well of the active region because of difference in growth conditions (such as growth temperature) between quantum well and EBL layers. A consequence of having such EBL layer in contact with the quantum well is that the indium composition of this quantum well would be greatly affected. It is then recommended to remove the spike in the valence band on the active region side of the EBL while having a barrier layer between the last quantum well of the active region and the EBL. Another known approach for improving the hole injection in the active region of an LED despite the presence of the electron blocking layer is to grade the composition of the EBL on the p-type layer side of the EBL. This approach is described in WO patent application 2006/074916 A1 (published Jul. 20, 2006). It teaches that a continuous grading of the aluminium composition from the p-type hole supply layer side of the EBL can induce polarisation doping, so a higher hole concentration is achieved than when using only magnesium doping. Alternatively, the polarisation doping can replace the magnesium doping to generate holes.

However, to generate holes via polarisation doping, the EBL thickness has to be large, typically larger than 100 nm as described in this patent application. Growing such large EBL in a standard LED structure without causing a degradation of the crystal quality via strain relaxation is challenging because of the lattice mismatch between the GaN and AlGaN materials. That is why incorporating indium in the EBL composition is recommended to avoid strain relaxation. However, incorporating indium in the EBL would require using a lower temperature than what is generally used for growing a typical AlGaN EBL in commercial near-ultraviolet, blue and green LEDs. The consequence of a lower EBL growth temperature would be a lower crystal quality which would affect ultimately the LED performance. Accordingly, merely incorporating indium is not appropriate for making commercially-grade near-ultraviolet, blue and green LEDs.

### SUMMARY OF THE INVENTION

In view of the above deficiencies of conventional LEDs, it is an object of the present invention to address the above problems by providing an LED with high efficiency, wherein the EBL has a high aluminium composition so the electron leakage is reduced without sacrificing the hole injection efficiency.

The present invention seeks to improve the internal efficiency of a semiconductor LED by reducing the leakage of the injected electrons from the active region.

The present invention describes a light emitting diode that includes a multi-quantum well active region and an electron blocking layer, wherein the aluminium composition of the electron blocking layer is graded on both sides of the electron blocking layer.

According to one aspect of the invention, the light emitting diode is fabricated in the (Al,In,Ga)N material system.

According to another aspect of the invention, the electron blocking layer may be, for example, AlₓGa₁₋ₓN or InₓAl_{y}Ga_{1-x-y}N.

### BRIEF DESCRIPTION OF THE DRAWINGS

FIG. 1 illustrates the band structure for a reference LED.

FIG. 2 is a cross sectional view of a light emitting device according to exemplary embodiments of the invention.

FIG. 3 is a cross sectional view of an electron blocking region of FIG. 2, according to exemplary embodiments of the invention.

FIG. 4 is a cross sectional view of another electron blocking region of FIG. 2, according to exemplary embodiments of the invention.

FIG. 5 illustrates the band structure for a reference LED and for a first example of the electron blocking region illustrated in FIG. 4 according to exemplary embodiments of the invention.

FIG. 6A graphically illustrates the IV characteristics of a reference light emitting device and of a light emitting device having an electron blocking region as illustrated in FIG. 4, according to exemplary embodiments of the invention.

FIG. 6B graphically illustrates internal quantum efficiency of a reference light emitting device and of a light emitting device having an electron blocking region as illustrated in FIG. 4, according to exemplary embodiments of the invention.

FIG. 7 graphically illustrates the normalised internal quantum efficiency at a current density of 50 A/cm² for different values of the maximum aluminium composition fraction in the electron blocking region according to exemplary embodiments of the invention.

FIG. 8 graphically illustrates the normalised internal quantum efficiency at a current density of 50 A/cm² for different thickness of the upgraded layer of the electron blocking region according to exemplary embodiments of the invention.

FIG. 9A graphically illustrates the normalised internal quantum efficiency at a current density of 50 A/cm² for different thickness of the upgraded and downgraded layer of the electron blocking region according to exemplary embodiments of the invention.

FIG. 9B illustrates the band structure for the electron blocking region illustrated in FIG. 8A according to exemplary embodiments of the invention.

FIG. 10 graphically illustrates the operating voltage at a current density of 50 A/cm² for different thickness of the upgraded and middle layers of the electron blocking region according to exemplary embodiments of the invention.

FIG. 11 is a cross sectional view of another electron blocking region of FIG. 2, according to exemplary embodiments of the invention.

FIG. 12 is a cross sectional view of another electron blocking region of FIG. 2, according to exemplary embodiments of the invention.

FIG. 13 is a cross sectional view of another electron blocking region of FIG. 2, according to exemplary embodiments of the invention.

FIG. 14A is a plan view and FIG. 14B is a cross sectional view of a light emitting diode, according to exemplary embodiments of the invention.

FIG. 15 is a band diagram of a light emitting diode according to exemplary embodiments of the invention.

### DETAILED DESCRIPTION OF THE INVENTION

The preferred embodiments of the invention will be described with reference to the drawings.

A device of the present invention may be grown by any suitable means and on any suitable substrate as are known in the art, which include but are not limited to: sapphire such as c-plane, a-plane, m-plane, r-plane and other faces, Silicon such as (111) plane and (100) plane, GaN such as c-plane, a-plane, m-plane, r-plane and other faces or SiC with various faces. Off-angled substrates such as 0.35 degrees inclined from c-plane sapphire or 2 degrees inclined from c-plane GaN may be used. The face of the substrates may be flat or patterned.

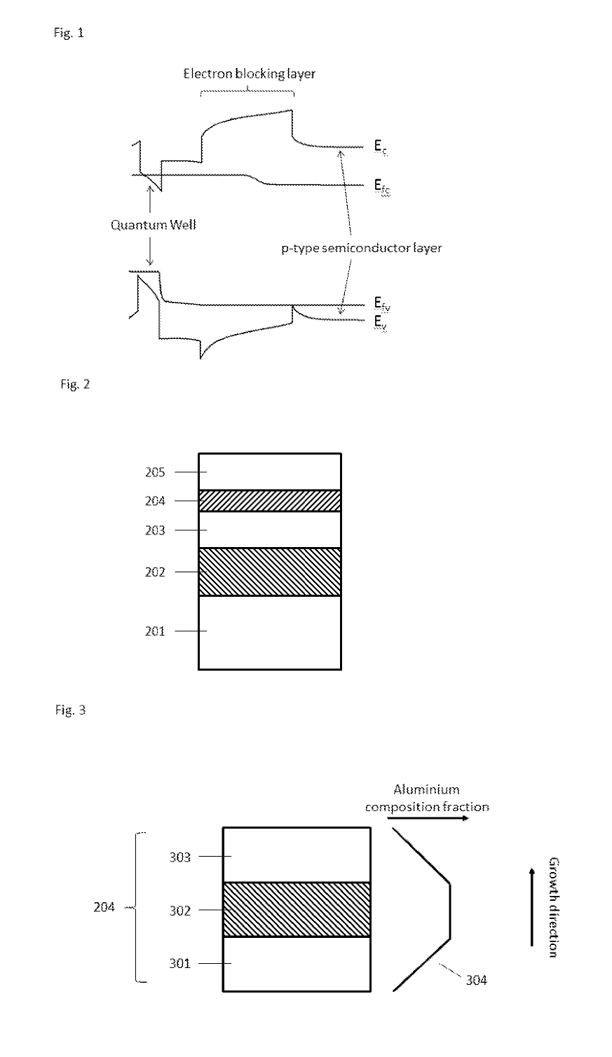

Exemplary embodiments of the present invention will be described with reference to FIG. 2. FIG. 2 shows a schematic of a light emitting diode fabricated in the (Al,In,Ga)N material system and may contain a sapphire substrate 201, a n-type (Al,In,Ga)N layer 202 disposed on top of the sapphire substrate 201, a light emitting region 203 disposed on top of the n-type layer 202, an (Al,In,Ga)N electron blocking layer 204 disposed on top of the light emitting region 203, and a first p-type (Al,In,Ga)N layer 205.

As used herein, the light emitting region of a light emitting device refers to the region in which majority and minority electronic carriers (e.g., holes and electrons) recombine to produce light. In general, an active region can include a quantum well structure, wherein the total number of quantum wells is at least 1, and more preferably greater than 2, and preferably more than 6, and preferably less than 20, and more preferably less than 14, and the quantum well layers are fabricated in the (Al,In,Ga)N material system.

The electron blocking layer 204 might be undoped but is preferably doped with magnesium such as it is p-type.

Generally, an aspect of the invention is a group III nitride-based light emitting device. In exemplary embodiments, the device includes an n-type semiconductor layer; a first p-type semiconductor layer; an active region; and an electron blocking region comprising AlGaInN located between the active region and the first p-type semiconductor layer, and including at least an upgraded layer and a downgraded layer. An aluminium composition of the upgraded layer of the electron blocking region increases from an active region side to a first p-type semiconductor layer side of the electron blocking region, and an aluminium composition of the downgraded layer of the electron blocking region decreases from the active region side to the first p-type semiconductor layer side of the electron blocking region. The nitride-based light emitting device may be a light emitting diode or a laser diode.

An example of an electron blocking region 204 with 3 layers according to a first embodiment of this invention is represented in FIG. 3, and may contain: a upgraded layer 301, a middle layer 302 disposed on the upgraded layer 301 and a downgraded layer 303 disposed on top of the middle layer 302. Because of the existence of the middle layer 302, the maximum aluminium composition of the electron blocking region under mass production is stabilized.

In this example, the three layers 301, 302 and 303 of the electron blocking region 204 include, but are not limited to, AlₓIn_{y}Ga_{1-x-y}N wherein 0<x≦1 and 0≦y<1. Specifically smaller In composition, for example 0≦y<0.05, is preferable to maintain wide bandgap, and in such a case Al composition x may represent the bandgap of the layer. Moreover, in this example, the three layers 301, 302 and 303 of the electron blocking region 204 have all the same thickness. However, the three layers 301, 302 and 303 may have different thicknesses.

The composition of each of the layers of the electron blocking region 204 will be described according to the first embodiment of this invention, with reference to FIG. 3 and to the aluminium composition profile 304 of FIG. 3.

The upgraded layer 301 is made of AlₓIn_{y}Ga_{1-x-y}N, wherein the aluminium composition fraction x of the upgraded layer 301 is varied linearly along the growth direction from a minimum value at the interface between the light emitting region 203 and the upgraded layer 301 of the electron blocking region 204, to a maximum value at the interface between the upgraded layer 301 and the middle layer 302 of the electron blocking layer 204.

The middle layer 302 is made of AlₓIn_{y}Ga_{1-x-y}N, wherein the aluminium composition fraction x of the middle layer 302 is constant or approximately constant. In this first embodiment of the invention the aluminium composition fraction value of the middle layer 302 is the same as the maximum aluminium composition fraction value of the upgraded layer 301.

Finally the downgraded layer 303 is made of AlₓIn_{y}Ga_{1-x-y}N, wherein the aluminium composition fraction x of the downgraded layer 303 is varied linearly along the growth direction from a maximum value at the interface between the middle layer 302 and the downgraded layer 303 of the electron blocking region 204, to a minimum value at the interface between the downgraded layer 303 of the electron blocking layer 204 and the first p-type (Al,In,Ga)N layer 205. In this first embodiment of the invention the maximum aluminium composition fraction value of the downgraded layer 303 is the same as the aluminium composition fraction value of the middle layer 302.

To further illustrate the composition variation of the aluminium composition in each of the layers, FIG. 3 is also representing the profile of the aluminium composition 304 within the electron blocking region 204.

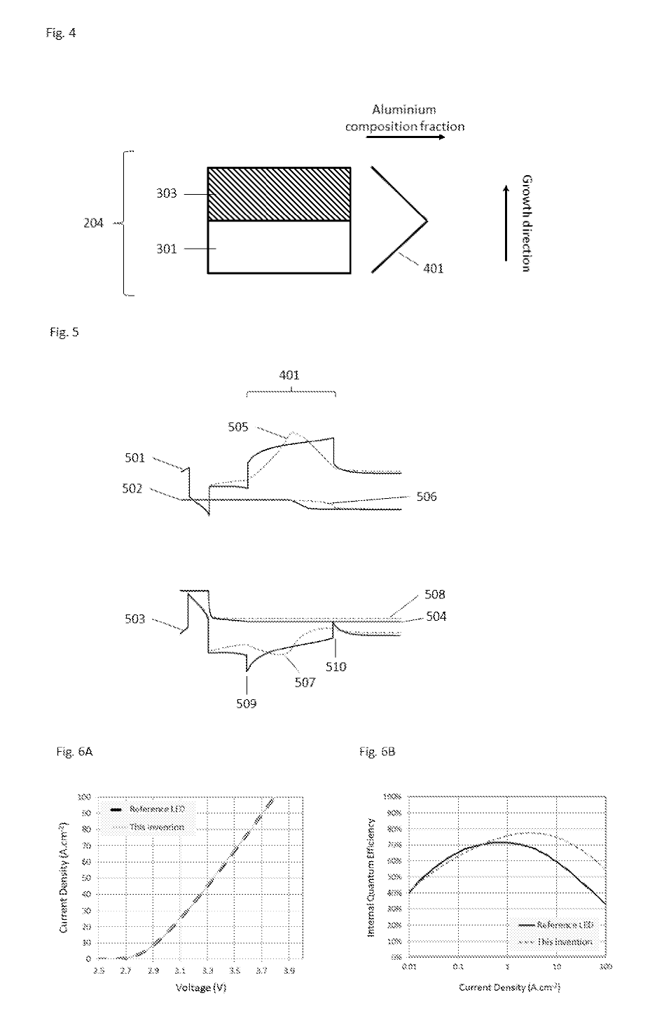

In a second embodiment of the present invention, the middle layer 302 of the electron blocking region 204 has a thickness of 0 nm, i.e., the electron blocking region includes only two layers 301 and 303. The aluminium composition in the two layers 301 and 303 of the electron blocking region 204 is the same as described in the first embodiment. The electron blocking region structure 204 and its respective aluminium composition profile 401 of the second embodiment are illustrated in FIG. 4

Such composition profile in each of the layers of the electron blocking region 204 has an effect on the conduction band and valence band profile. FIG. 5 is comparing the simulation results from a reference LED structure which is similar to FIG. 2, wherein the electron blocking region 204 is made of a single layer of AlₓGa₁₋ₓN, to an LED structure having an electron blocking layer as described in this second embodiment and illustrated in FIG. 4. In this example, the aluminium composition fraction of the electron blocking region of the reference LED is constant at 0.22 and the thickness of the electron blocking region is 18 nm. Also in this example, but not limiting the scope of this invention, the aluminium composition fraction of the upgraded layer 301 of the electron blocking region 204 of the LED related to this invention is linearly graded from 0 to 0.3, and the aluminium composition fraction of the downgraded layer 303 of the electron blocking region is linearly graded from 0.3 to 0. The thickness of both layers is 9 nm, such that the total thickness of the electron blocking region of the LED related to this invention is 18 nm. For the simulation results presented in FIG. 5, the other LED structure parameters for both the reference LED and the LED related to this invention are, for example: the first p-type layer 205 is made of 80 nm of GaN with a p-type dopant concentration of 3.00×10¹⁹ cm⁻³; the electron blocking region 204 has a p-type dopant concentration of 1.00×10¹⁹ cm⁻³; and the active region 203 comprises eight 3.5 nm thick In_{0.15}Ga_{0.85}N quantum wells separated by 4 nm thick GaN barrier layers. In this particular example, the emission wavelength from the reference LED and the LED related to this invention is around 450 nm.

Reference is made more particularly to the bottom portion of FIG. 5. The bottom portion of FIG. 5 represents the valence band 503 and the hole Fermi level 504 of the standard LED and the valence band 507 and the hole Fermi level 508 of the LED structure of this second embodiment (as in FIG. 4). The valence band 503 related to the electron blocking layer 204 of the standard LED exhibits two spikes 509 and 510 respectively at the interfaces between the last GaN barrier of the active region 203 and the electron blocking layer 204, and between the electron blocking layer 204 and the first p-type GaN layer 205 of the LED. These two spikes are caused by the difference in polarisation fields between the AlGaN electron blocking layer and the GaN layers.

At a similar injection current of 50 A/cm², which corresponds to a current in the efficiency droop regime, the valence band profile 507 of the electron blocking region 204 of the LED structure of this second embodiment (as in FIG. 4) does not exhibit such spikes as does the reference LED structure described above, despite the higher aluminium composition. Then the hole injection is not restricted by the presence of these spikes and the operating voltage of the LED structure of this second embodiment is similar to the operating voltage of the reference LED although the electron blocking layer's aluminium composition fraction of the LED of this embodiment reaches 0.3 and the aluminium composition fraction in the reference LED's electron blocking layer is 0.22. This is illustrated in FIG. 6A which represents the simulation results of the IV characteristics for both LED structures.

Reference further is made to the top portion of FIG. 5. The top portion of FIG. 5 represents the valence band 501 and the hole Fermi level 502 of the standard LED and the valence band 505 and the hole Fermi level 506 of the LED structure of this second embodiment (as in FIG. 4). Because the maximum value of the aluminium composition fraction in the electron blocking region is larger in the embodiment of FIG. 4 than for the reference LED, the energy barrier for the electrons in the conduction band 505 is larger than for the standard LED 501. As a consequence the electron leakage is reduced and the internal quantum efficiency (IQE) is improved. This is illustrated in FIG. 6B which represents the simulation result of the IQE of the standard LED and of the LED as described in this second embodiment. The IQE of the LED structure described in the second embodiment of the present invention is higher than for the standard LED structure for current densities larger than around 1A.cm⁻², and also exhibits a lower efficiency droop.

Although the invention has been described with a particular structure in this second embodiment, as shown in FIG. 4, it will be apparent to those skilled in the art that variations of this structure are possible without departing from the spirit or scope of the invention.

For example, the minimum aluminium composition fraction value of the upgraded AlₓIn_{y}Ga_{1-x-y}N layer 301 of the electron blocking region 204 can be different from 0 and can be different from the minimum value of the downgraded layer 303, which can also be different from 0. Similarly, the maximum value of the aluminium composition fraction of the upgraded layer 301 can be different from the maximum aluminium composition fraction value of the downgraded layer 303.

The minimum value of the aluminium composition fraction of the upgraded AlₓIn_{y}Ga_{1-x-y}N layer 301 of the electron blocking region 204 may be, but is not limited to, 0≦x<1, and more preferably 0≦x≦1, and more preferably x=0. Similarly, The minimum value of the aluminium composition fraction of the downgraded AlₓIn_{y}Ga_{1-x-y}N layer 303 of the electron blocking region 401 may be, but is not limited to, 0≦x<1, and more preferably 0≦x≦0.1, and more preferably x=0.

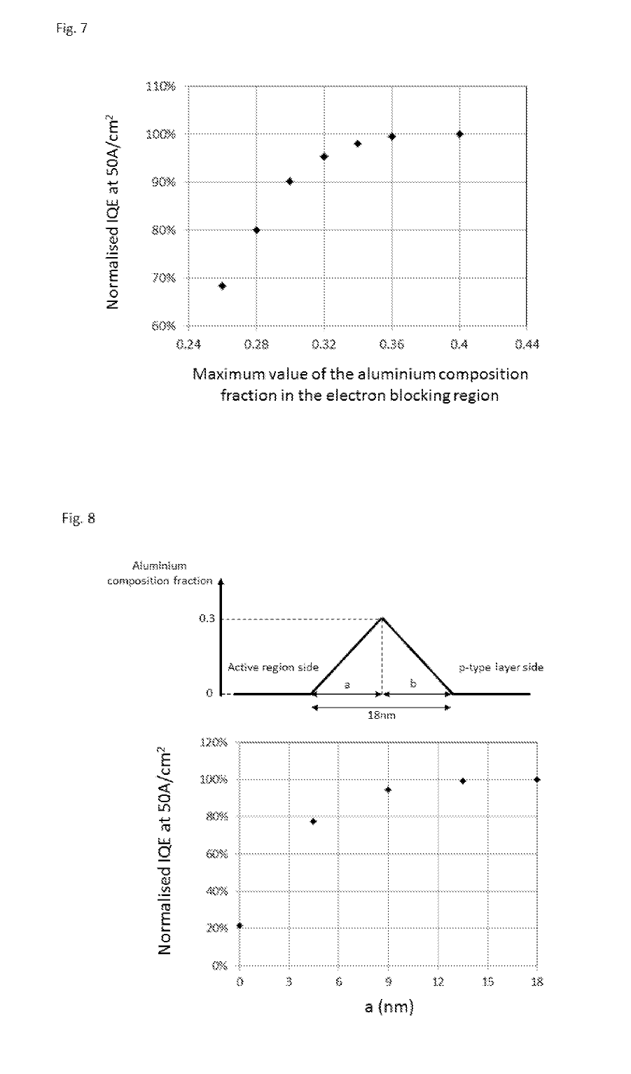

The maximum value of the aluminium composition fraction of the upgraded AlₓIn_{y}Ga_{1-x-y}N layer 301 of the electron blocking region 204 may be, but is not limited to, 0<x≦1, and more preferably 0.2≦x≦0.5, and more preferably 0.28×0.4. Similarly, the maximum value of the aluminium composition fraction of the downgraded AlₓIn_{y}Ga_{1-x-y}N layer 303 of the electron blocking region 204 may be, but is not limited to, 0<x≦1, and more preferably 0.2≦x≦0.5, and more preferably 0.28≦x≦0.4. FIG. 7 is illustrating the simulation results of the IQE at a current density of 50 A/cm² (normalised to the IQE value at a maximum aluminium composition fraction of 0.4) of the LED as described in this example of the second embodiment (FIG. 4) as a function of the maximum value of the aluminium composition fraction in the upgraded and downgraded layers of the electron blocking region 204. The IQE, and consequently the LED output power, increases when the maximum aluminium composition fraction of the electron blocking region increases. Particularly, the IQE value starts to saturate when the maximum aluminium composition fraction reaches 0.3, and then reaches saturation for a maximum aluminium composition fraction greater than 0.4 in this particular example. Then, to achieve maximum efficiency (i.e. achieving a normalised IQE of at least 80% in FIG. 7), it is preferred that the maximum value of the aluminium composition fraction of the upgraded and downgraded AlₓIn_{y}Ga_{1-x-y}N layers of the electron blocking region 204 is, for example, 0.28≦x≦0.4. More generally, a maximum aluminium composition fraction value in the electron blocking region lower than 0.2 would not provide an energy barrier high enough to prevent serious electron leakage, and a value higher than 0.5 would be very difficult to achieve experimentally without degrading the crystal quality of the electron blocking region because of the large lattice mismatch between GaN and AlₓGa₁₋ₓN (x>0.5). An aluminium composition fraction value larger than 0.5 in the electron blocking region might also reduce significantly the activation energy of the magnesium doping, thus leading to a large increase of the operation voltage.

Although the preferred ranges of aluminium composition values for the electron blocking region described in this particular example are compared to a standard blue emitting nitride based LED structure, it will be apparent to those skilled in the art that these ranges can differ for other LED structures, such as LED structures emitting in the ultra-violet region of the spectrum which use for example an AlGaN substrate or AlGaN hole supply layer, and LED structures emitting in the green region of the spectrum which use higher In content well layers compared to that for blue LED.

Although in the example of this second embodiment the thickness of the upgraded layer 301 is equal to the thickness of the downgraded layer 303 of the electron blocking region 204, the thickness of the upgraded layer 301 can be different from the thickness of the downgraded layer 303. The effect of the respective thickness of the two layers of the electron blocking region 204 on the IQE will be described with reference to FIG. 8. For this particular example, the minimum aluminium composition fraction is set at 0 and the maximum aluminium fraction is set at 0.30. The aluminium composition profile of the electron blocking region is illustrated on top of FIG. 8. For this example, the total thickness a+b of the electron blocking layer is set to 18 nm, with “a” being the thickness of the upgraded layer 301 and “b” the thickness of the downgraded layer 303. When the thickness of the upgraded layer 301 of the electron blocking region 204 increases, the simulation results show an improvement of the internal quantum efficiency of the LED. This is because when the thickness of the upgraded layer 301 (thickness a in FIG. 8) increases, the energy barrier for the electrons provided by the electron blocking region increases, so the electron leakage decreases. In particular, the IQE starts to saturate when a=b. Then, it is then more preferable that a≧b to achieve maximum efficiency.

Although the total thickness of the electron blocking region in the example above is such as a+b=18 nm, other thicknesses are possible. The effect of the thickness of the upgraded layer 301 of the electron blocking region 204 on the IQE is illustrated in FIG. 9A. The IQE was calculated for 2 different thickness values of the downgraded layer 303 of the electron blocking region 204 such as b=0 nm and b=2 nm. The simulation results show that the IQE increases when the thickness of the upgraded layer 301 increases and reaches saturation for a upgraded layer 301 thickness of around 40-60 nm. So the thickness of the upgraded layer 301 of the electron blocking region 204 is preferably equal to or less than 100 nm, and more preferably equal to or less than 50 nm.

Moreover, the simulation results of FIG. 9A show that grading the aluminium composition of the first p-type layer 205 side of the electron blocking region provides a better IQE (The IQE values for b=2 nm are higher than for b=0 nm in FIG. 9A). In FIG. 9B the computed valence bands and hole Fermi levels of the electron blocking region where the thickness of the downgraded layer 303 is b=0 nm and b=2 nm are represented respectively by the black and grey lines. When the aluminium composition is graded on the hole supply layer side of the electron blocking region (i.e. when b=2 nm), the spike in the valence band does not reach the hole Fermi level (grey curve of FIG. 9B), i.e. the holes are not captured in this energy trap. The hole injection efficiency is then improved, and consequently the IQE is improved. In conclusion, in this second embodiment, the downgraded layer 303 of the electron blocking region 204 has a thickness equal to or larger than 1 nm, and more preferably has a thickness equal to or larger than 2 nm.

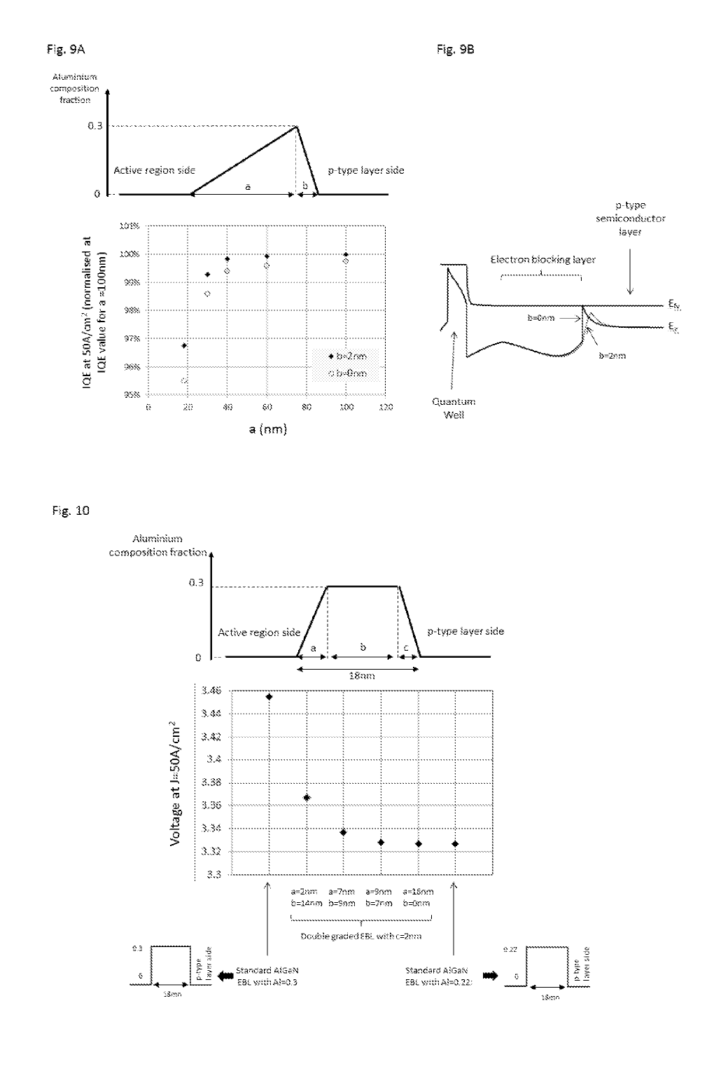

Similarly to the example of the second embodiment, the thickness of the three layers of the electron blocking region 204 described in the first embodiment, and illustrated in FIG. 3, can have different values. The effect of the respective thickness of the three layers of the electron blocking region on the IQE will be described with reference to FIG. 10. For this particular example, the minimum aluminium composition fraction is set at 0 and the maximum aluminium fraction is set at 0.3. The aluminium composition profile of the electron blocking region is illustrated on top of FIG. 10. For this example, the total thickness a+b+c of the electron blocking layer is set to 18 nm, with “a” being the thickness of the upgraded layer 301, “b” the thickness of the middle layer 302 and “c” the thickness of the downgraded layer 303. The thickness of the downgraded layer 303 is also set to c=2 nm. The graph in FIG. 10 illustrates the operating voltage at a current density of 50 A/cm² for different thickness of the upgraded and middle layers. The operating voltage decreases when the thickness of the upgraded layer 301 (downgraded layer 303) of the electron blocking region 204 increases (decreases). More particularly, the operating voltage becomes similar to the operating voltage of a reference LED having a standard 18 nm thick electron blocking layer made of Al_{0.22}Ga_{0.78}N when a≧b. On the same graph is shown that the operating voltage of the LED with double graded electron blocking region is lower than for a reference LED having a standard Al_{0.3}Ga_{0.7}N electron blocking layer with the same aluminium fraction of 0.3, for any value of a and b.

So, and in light of these results, although the thickness of the three layers of the electron blocking region 204 can take any values, except a=0 nm and c=0 nm, the thickness of the upgraded layer 301 is preferably sensibly larger than the thickness of the middle layer 302 such that a≧D. Moreover (and in light of the results of the second embodiment), the thickness of the upgraded layer 301 is also preferably sensibly larger than the thickness of the downgraded layer 303 such that a≧c. Moreover, the thickness of the upgraded layer 301 is preferably less than 100 nm, and more preferably less than 50 nm. The thickness of the downgraded layer 303 is sensibly equal to or more than 1 nm, and preferably equal to or more than 2 nm.

Having the thickness of the three layers of the electron blocking region 204 such that a≧b and a≧c provides also an advantage for the growth quality of the electron blocking region for high aluminium composition fraction, i.e. for x>0.2. Indeed, in this case, the portion of the electron blocking layer having an aluminium composition fraction higher than 0.2 is smaller than half of the total thickness of the electron blocking region. The crystal quality of the electron blocking layer is then improved compared to a standard electron blocking layer having a constant aluminium composition fraction higher than 0.2 along all its thickness, as well as providing a high energy barrier to the electrons so the electron leakage is reduced.

Although in this example the minimum value of the aluminium composition fraction of the upgraded layer 301 and downgraded layer 303 was set to 0 and the maximum value of the aluminium composition fraction of the upgraded layer 301 and downgraded layer 303 was set to 0.3, other aluminium composition fraction can be used. The minimum value of the aluminium composition fraction of the upgraded AlₓIn_{y}Ga_{1-x-y}N layer 301 of the electron blocking region 204 of FIG. 3 may be, but is not limited to, 0≦x<1, and more preferably 0≦x≦0.1, and more preferably x=0. Similarly, the minimum value of the aluminium composition fraction of the downgraded AlₓIn_{y}Ga_{1-x-y}N layer 303 of the electron blocking region 204 of FIG. 3 may be, but is not limited to, 0≦x<1, and more preferably 0≦x≦0.1, and more preferably x=0.

The maximum value of the aluminium composition fraction of the upgraded AlₓIn_{y}Ga_{1-x-y}N layer 301 of the electron blocking region 204 of FIG. 3 may be, but is not limited to, 0<x≦1, and more preferably 0.2≦x≦0.5, and more preferably 0.28≦x≦4. Similarly, the maximum value of the aluminium composition fraction of the downgraded AlₓIn_{y}Ga_{1-x-y}N layer 303 of the electron blocking region 204 of FIG. 3 may be, but is not limited to, 0<x≦1, and more preferably 0.2≦x≦0.5, and more preferably 0.28≦x≦0.4.

Finally the aluminium composition fraction of the middle layer 302 of the electron blocking region 204 may be, but is not limited to, 0<x≦1, and more preferably 0.2≦x≦0.5, and more preferably 0.28≦x≦0.4.

Moreover, the middle layer 302 of the electron blocking region 204 in FIG. 3 may have one or more sections within its thickness where the aluminium composition is different.

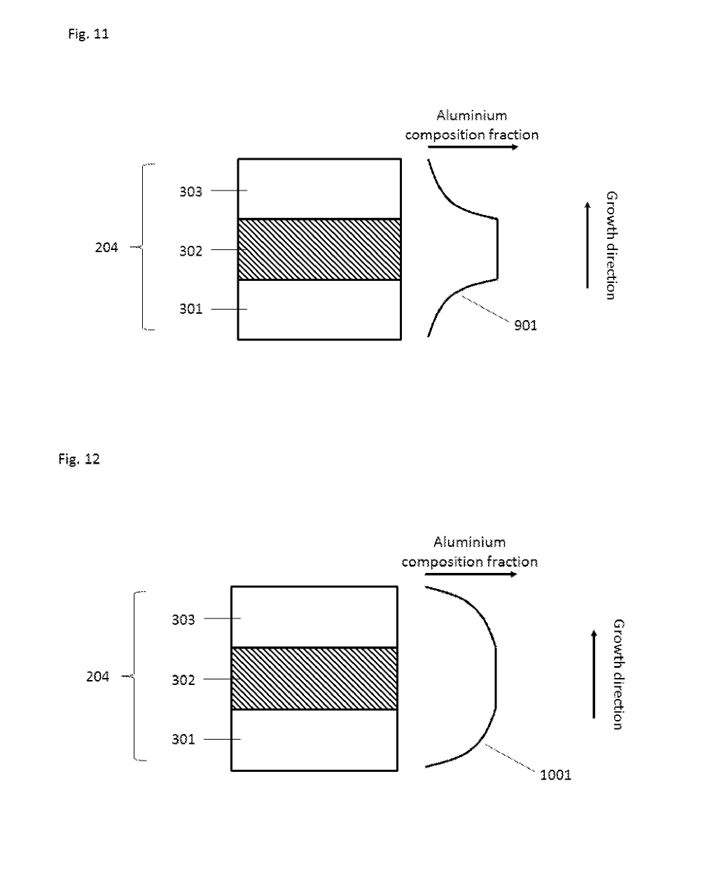

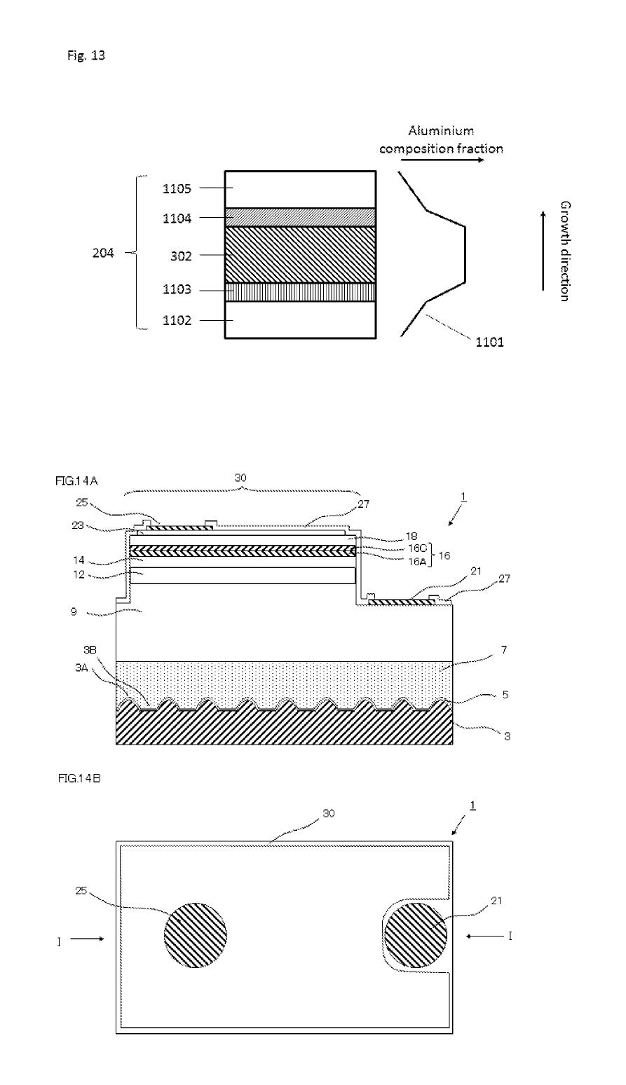

In a third embodiment of the present invention, and as illustrated in FIG. 11 and FIG. 12, the aluminium composition profile of the upgraded 301 and downgraded 303 layers of the electron blocking region 204 can be non-linear. More specifically the gradient of aluminium composition of the upgraded layer 301 and/or the downgraded layer is larger as the aluminium composition increases. The gradient shape can be exponential, logarithmic or polynominal. This structure has an advantage that the low-crystal quality high Al composition region can be smaller.

In a fourth embodiment of the present invention, the aluminium composition profile in the upgraded and downgraded layers of the electron blocking region 204 can be non-monotonous, i.e. the aluminium composition in the upgraded layer 301 (downgraded layer 303) can increase (decrease) with a different gradient in one or more sections within the thickness of the upgraded (downgraded) layer. One example of such aluminium composition profile within the electron blocking region is illustrated in FIG. 13: the aluminium composition in the upgraded layer increases more quickly in the second section 1103 than in the first section 1102 of the upgraded layer. As a variation of non-monotonous manner, stairstep-like gradient is also possible.

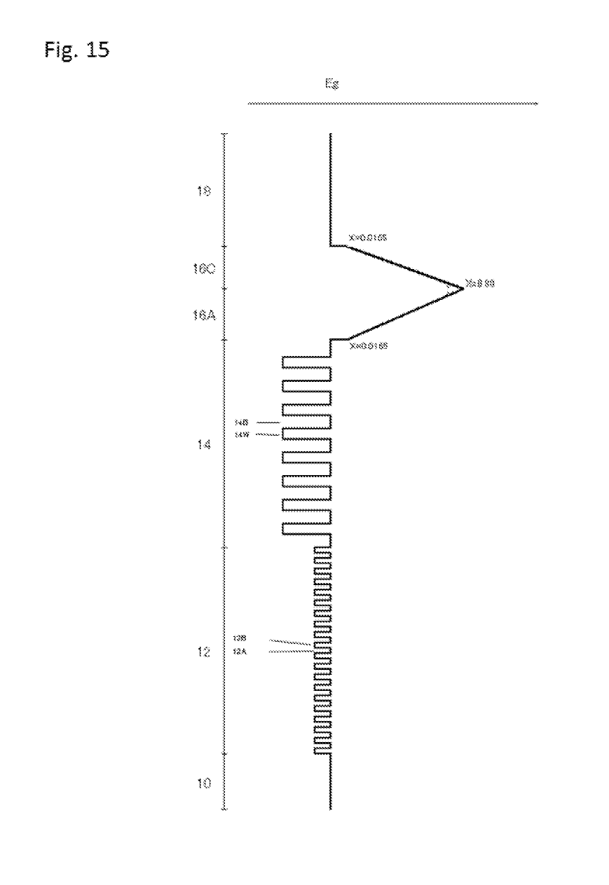

FIG. 14A and FIG. 14B show a sectional view and a plan view of an exemplary embodiment of a nitride-based light-emitting device 1, respectively. A sectional view along the line I-I shown in FIG. 14B corresponds to FIG. 14A. FIG. 15 is a band energy diagram schematically showing the magnitude of bandgap energy Eg from the n-type nitride-based layer 10 to the first p-type GaN layer 18.

In FIG. 14A, the upper surface of the substrate has a protrusion 3A and a relative concave region 3B (flat region). On the upper face of substrate 3, an AlN buffer layer 5, an undoped GaN layer 7, an n-doped GaN layer 9, a superlattice layer 12, a MQW light-emitting layer 14, a p-type electron blocking region 16 comprising a upgraded layer 16A and a downgraded layer 16C, and a first p-type GaN layer 18 (a hole supply layer) are stacked in this order to form mesa part 30. Outside of mesa part 30, a part of the upper face of n-type GaN layer 9 is exposed and an n-side electrode 21 is provided on it. On the first p-type GaN layer 18, a p-side transparent electrode 23 and a A-side electrode 25 are provided. The upper face of nitride-based light-emitting device 1, except for the surface of p-side electrode 25 and n-side electrode 21, is covered with a transparent protection film 27.

The n-type dopant is Si, and the n-type doping concentration in n-type GaN layers 9 is 1×10¹⁹ cm⁻³. The thickness of n-type GaN layers 9 is 5 um.

The superlattice layer 12 includes 20 pairs of alternately stacked wide bandgap layer 12A and narrow bandgap layer 12B. Wide bandgap layer includes GaN with 1.75 nm thickness, and narrow bandgap layer includes In_{0.08}Ga_{0.92}N with 1.75 nm thickness. Wide bandgap layer 12A and narrow bandgap layer 12B are n-type doped.

MQW light-emitting layer 14 includes 8 pairs of alternately stacked InₓGa₁₋ₓN well 14W and GaN barrier 14B. The Indium composition x is determined so that the emission wavelength is 450 nm. The thickness of well 14W is 4 nm and the thickness of barrier 14B is 5 nm. Well 14W and barrier 14B are undoped.

The electron blocking region 16 includes 9 nm upgraded layer 16A and 9 nm downgraded layer 16C, but the ratio of the thickness of layers 16A and 16C can be changed according to the simulation results FIG. 8, FIG. 9 and FIG. 10. In the electron blocking region 16, the designed starting composition X in AlₓGa₁₋ₓN of the upgraded layer 16A is not 0 but 0.0165 mainly because of controlling the Al source using a mass flow controller. For the same reason, the designed ending composition X in the downgraded layer 16C is also 0.0165. Thus the electron blocking region 16 has a kind of non-monotonous structure. The designed maximum composition X in AlₓGa₁₋ₓN at the interface of the upgraded layer 16A and the downgraded layer 16C is 0.3, but the actual composition is assumed to be shown by the dotted line in FIG. 15. The structure shown by the dotted line is also interpreted as a middle layer with convex aluminium composition.

N-side electrode 21 and p-side electrode 25 are electrodes for supplying nitride-based light-emitting device 1 with drive power. n-side electrode 21 and p-side electrode 25 include exclusively a pad electrode portion in FIG. 2, however, an elongated projecting portion (branch electrode) for current diffusion may be connected to n-side electrode 21 and p-side electrode 25. Transparent electrode 23 is preferably a transparent conductive film made of ITO (Indium Tin Oxide).

The nitride-based light emitting device 1 measures 440 um×530 um in plan view.

Example 1 is the nitride-based light emitting device 1 mounted on a TO-18 stem, and light output was measured without covering resin sealing. At a drive current of 100 mA (current density J=48 A/cm²) in an environment temperature of 25° C., light output P1(25)=146.0 mW (dominant wavelength 450 nm) was obtained. At a drive current of 100 mA in an environment temperature of 80° C., light output P1 (80)=138.8 mW was obtained. Since P1 (80)/P1 (25)=95.1%, the light output was not strongly dependent on the temperature, thus Example 1 is suitable for high temperature operation due to self-heating.

For comparison, Comparative Example 1 whose structure is identical to Example 1 except that the electron blocking region 16 (18 nm thickness) is replaced to p-type Al_{0.22}Ga_{0.78}N of 18 nm thickness was prepared.

Comparative Example 1 was also mounted on a TO-18 stem, and light output was measured without a covering resin sealing. At a drive current of 100 mA in an environment temperature of 25° C., light output Pc (25)=138.7 mW (dominant wavelength 450 nm) was obtained. At a drive current of 100 mA in an environment temperature of 80° C., light output Pc (80)=131.8 mW was obtained. Thus the increase of power P1(25)/Pc (25) is 105.3%, while the increase of power P1(80)/Pc (80) is 105.3%.

Though the increase of light output is smaller than that of the simulation data, the improvement of performance in this invention has been confirmed. The discrepancy of increase between simulation and actual data may be because of the incomplete experiment, such that the experimental electron blocking region is not exactly the same as that as designed. The dotted line in FIG. 15 shows the estimated Eg profile, while the designed structure has the sharp peak as solid line. But other reasons may be responsible for the discrepancy.

Although the preferred ranges of aluminium composition values and thickness values for the electron blocking region described in the previous embodiments were described by using an example of a standard blue emitting nitride based LED structure, it will be apparent to those skilled in the art that these ranges can also apply to other LED structures emitting at different wavelengths, such as LED structures emitting in the near ultra-violet region of the spectrum (from 380 nm) up to the green region of the spectrum (to 560 nm). It will also be apparent to those skilled in the art that when using this invention in LEDs emitting in the ultra-violet region of the spectrum and which use for example an AlGaN substrate and/or an AlGaN hole supply layer, then the preferred ranges of aluminium composition values might have to be changed accordingly (i.e. higher aluminium composition values might have to be used).

In accordance with the above, an aspect of the invention is a group III nitride-based light emitting device. In exemplary embodiments, the device includes an n-type semiconductor layer; a first p-type semiconductor layer; an active region; and an electron blocking region comprising AlGaInN located between the active region and the first p-type semiconductor layer, and comprising at least an upgraded layer and a downgraded layer. An aluminium composition of the upgraded layer of the electron blocking region increases from an active region side to a first p-type semiconductor layer side of the electron blocking region, and an aluminium composition of the downgraded layer of the electron blocking region decreases from the active region side to the first p-type semiconductor layer side of the electron blocking region.

In an exemplary embodiment of the nitride-based light emitting device, the layers of the electron blocking region are AlGaN.

In an exemplary embodiment of the nitride-based light emitting device, the aluminium composition of the upgraded or downgraded layers of the electron blocking region varies in a linearly manner.

In an exemplary embodiment of the nitride-based light emitting device, the aluminium composition of the upgraded or downgraded layers of the electron blocking region varies in one of an exponential, logarithmic or polynominal manner.

In an exemplary embodiment of the nitride-based light emitting device, the aluminium composition of the upgraded or downgraded layers of the electron blocking region varies in a non-monotonous manner.

In an exemplary embodiment of the nitride-based light emitting device, the electron blocking region comprises a middle layer between the upgraded layer and the downgraded layer.

In an exemplary embodiment of the nitride-based light emitting device, an aluminium composition of the middle layer between the upgraded layer and the downgraded layer is constant.

In an exemplary embodiment of the nitride-based light emitting device, a thickness of the upgraded layer of the electron blocking region is equal to or less than 100 nm.

In an exemplary embodiment of the nitride-based light emitting device, the thickness of the upgraded layer of the electron blocking region is equal to or less than 50 nm.

In an exemplary embodiment of the nitride-based light emitting device, a thickness of the downgraded layer of the electron blocking region is equal to or greater than 1 nm.

In an exemplary embodiment of the nitride-based light emitting device, the thickness of the downgraded layer of the electron blocking region is equal to or greater than 2 nm.

In an exemplary embodiment of the nitride-based light emitting device, a thickness of the upgraded layer is larger than a thickness of the downgraded layer.

In an exemplary embodiment of the nitride-based light emitting device, the thickness of the downgraded layer is equal to or more than 2 nm.

In an exemplary embodiment of the nitride-based light emitting device, a middle layer is located between the upgraded layer and the downgraded layer, and the thickness of the upgraded layer is equal to or larger than a thickness of the middle layer.

In an exemplary embodiment of the nitride-based light emitting device, a maximum aluminium composition fraction of the electron blocking region is between 0.2 and 0.5.

In an exemplary embodiment of the nitride-based light emitting device, the maximum aluminium composition fraction of the electron blocking region is between 0.28 and 0.4.

In an exemplary embodiment of the nitride-based light emitting device, the nitride-based light emitting device is a light emitting diode.

In an exemplary embodiment of the nitride-based light emitting device, the nitride-based light emitting device is a laser diode.

Many different embodiments have been disclosed herein, in connection with the above description and the drawings. It will be understood that it would be unduly repetitious and obfuscating to literally describe and illustrate every combination and sub-combination of these embodiments. Accordingly, all embodiments can be combined in any way and/or combination, and the present specification, including the drawings, shall be construed to constitute a complete written description of all combinations and sub-combinations of the embodiments described herein, and of the manner and process of making and using them, and shall support claims to any such combination or sub-combination.

### INDUSTRIAL APPLICABILITY

The present invention is applicable for manufacturing light emitting diodes LEDs for a variety of uses, including for example, backlights for liquid crystal displays, headlamps for automobiles, general lighting, lasers for optical recording devices, and other suitable applications in which LEDs are employed.

1. A group III nitride-based light emitting device, comprising
an n-type semiconductor layer;
a first p-type semiconductor layer;
an active region; and
an electron blocking region comprising AlGaInN located between the active region and the first p-type semiconductor layer, and comprising at least an upgraded layer and a downgraded layer,
wherein an aluminium composition of the upgraded layer of the electron blocking region increases from an active region side to a first p-type semiconductor layer side of the electron blocking region, and an aluminium composition of the downgraded layer of the electron blocking region decreases from the active region side to the first p-type semiconductor layer side of the electron blocking region.

2. The nitride-based light emitting device according to claim 1, wherein the layers of the electron blocking region are AlGaN.

3. The nitride-based light emitting device according to claim 1, wherein the aluminium composition of the upgraded or downgraded layers of the electron blocking region varies in a linearly manner.

4. The nitride-based light emitting device according to claim 1, wherein the aluminium composition of the upgraded or downgraded layers of the electron blocking region varies in one of an exponential, logarithmic or polynominal manner.

5. The nitride-based light emitting device according to claim 1, wherein the aluminium composition of the upgraded or downgraded layers of the electron blocking region varies in a non-monotonous manner.

6. The nitride-based light emitting device according to claim 1, wherein the electron blocking region comprises a middle layer between the upgraded layer and the downgraded layer.

7. The nitride-based light emitting device according to claim 6, wherein an aluminium composition of the middle layer between the upgraded layer and the downgraded layer is constant.

8. The nitride-based light emitting device according to claim 1, wherein a thickness of the upgraded layer of the electron blocking region is equal to or less than 100 nm.

9. The nitride-based light emitting device according to claim 8, wherein the thickness of the upgraded layer of the electron blocking region is equal to or less than 50 nm.

10. The nitride-based light emitting device according to claim 1, wherein a thickness of the downgraded layer of the electron blocking region is equal to or greater than 1 nm.

11. The nitride-based light emitting device according to claim 10, wherein the thickness of the downgraded layer of the electron blocking region is equal to or greater than 2 nm.

12. The nitride-based light emitting device according to claim 1, wherein a thickness of the upgraded layer is larger than a thickness of the downgraded layer.

13. The nitride-based light emitting device according to claim 12, wherein the thickness of the downgraded layer is equal to or more than 2 nm.

14. The nitride-based light emitting device according to claim 12, wherein a middle layer is located between the upgraded layer and the downgraded layer, and the thickness of the upgraded layer is equal to or larger than a thickness of the middle layer.

15. The nitride-based light emitting device according to claim 1, wherein a maximum aluminium composition fraction of the electron blocking region is between 0.2 and 0.5.

16. The nitride-based light emitting device according to claim 15, wherein the maximum aluminium composition fraction of the electron blocking region is between 0.28 and 0.4.

17. The nitride-based light emitting device of claim 1, wherein the nitride-based light emitting device is a light emitting diode.

18. The nitride-based light emitting device of claim 1, wherein the nitride-based light emitting device is a laser diode.
